(19) United States
(12) Patent Application Publication
(10) Pub. No.: US 2012/0241883 A1
(43) Pub. Date: Sep. 27, 2012

(54) SPIN TRANSPORT DEVICE AND MAGNETIC HEAD

(75) Inventors: Tomoyuki SASAKI, Tokyo (JP); Tohru OIKAWA, Tokyo (JP); Yoshihiro TSUCHIYA, Tokyo (JP)

(73) Assignee: TDK CORPORATION, Tokyo (JP)

(21) Appl. No.: 13/409,844

(22) Filed: Mar. 1, 2012

(30) Foreign Application Priority Data
Mar. 23, 2011 (JP) 2011-064239

(51) Int. Cl. H01L 43/02

(52) U.S. Cl. 257/421; 257/E43.001

(57) ABSTRACT

The present invention provides a spin transport device having lowered areal resistance in its tunneling layer and a magnetic head. The spin transport device (magnetic sensor 1) comprises a channel layer 10 constituted by a semiconductor, ferromagnetic layers 20A, 20B formed on the channel layer 10, and tunneling layers 22A, 22B formed so as to be interposed between the channel layer 10 and ferromagnetic layers 20A, 20B, while the tunneling layers 22A, 22B are constituted by a material substituting a part of Mg in MgO with Zn. As a result of studies, the inventors observed a decrease in areal resistance in a tunnel material having substituted a part of Mg in MgO with Zn. Therefore, the tunneling layers 22A, 22B can lower their areal resistance when constructed by a material having substituted a part of Mg in MgO with Zn.

### BACKGROUND OF THE INVENTION

1. Field of the Invention

The present invention relates to a spin transport device and a magnetic head.

2. Related Background Art

Spin transport phenomena in semiconductors have recently been attracting much attraction. In particular, silicon is a material which serves as a basis for main semiconductor products at present, so that silicon-based spintronics, if achieved, can add new functions to silicon devices without discarding existing technologies.

An example is a spin-MOSFET disclosed in the following Patent Literature 1. The following Non-Patent Literature 1 has recently proved a spin transport phenomenon in silicon at room temperature, whereby movement for its application has begun. One of reasons why no spin transport phenomenon at room temperature has been observed until recently lies in the fact that the temperature dependence of the efficiency at which spins are injected into silicon drastically decreases as temperature rises (see the following Non-Patent Literatures 2 and 3). Causes have not been specified yet, though spin scattering at interfaces between silicon and tunnel materials is expected to be a main physical cause.

As materials (tunnel materials) for a tunneling layer formed on silicon, Al₂O₃ (the following Non-Patent Literature 4), SiO₂ (the following Non-Patent Literature 5), and MgO (the following Non-Patent Literature 6) have conventionally been known, each of which is a typical material in spintronics. Among these tunnel materials, MgO is a material which can achieve a coherent tunnel and thus is particularly suitable as a tunnel film for injecting spins.

### Patent Literature 1: Japanese Patent Application Laid-Open No. 2004-111904

### Non-Patent Literature 1: T. Suzuki et. al., Applied Physics Express 4 (2011), 023003

### Non-Patent Literature 2: T. Sasaki et. al., Applied Physics Letter 96(2010), 122101

### Non-Patent Literature 3: T. Sasaki et. al., Applied Physics Letter 98(2011), 012508

### Non-Patent Literature 4: Erve et. al., Applied Physics Letter 91(2007), 212109

### Non-Patent Literature 5: C. H. Li et. al., Applied Physics Letter 95(2009), 172102

### Non-Patent Literature 6: T. Sasaki et. al., Applied Physics Express 2 (2009), 053003

### Non-Patent Literature 7: F. J. Jedema Nature London 416(2002), 713

### SUMMARY OF THE INVENTION

When using crystalline MgO as a tunnel material and sequentially forming crystalline MgO and ferromagnetic layers on monocrystal silicon, the high areal resistance of MgO becomes a problem, whereby a material having lower areal resistance is desired.

For solving the problem mentioned above, it is an object of the present invention to provide a spin transport device having lowered areal resistance in its tunneling layer and a magnetic head.

The spin transport device in accordance with the present invention comprises a channel layer constituted by a semiconductor, a ferromagnetic layer formed on the channel layer, and a tunneling layer formed so as to be interposed between the channel and ferromagnetic layers, while the tunneling layer is constituted by a material substituting a part of Mg in MgO with Zn.

As a result of studies, the inventors observed a decrease in areal resistance in a tunnel material having substituted a part of Mg in MgO with Zn. Therefore, the tunneling layer can lower its areal resistance when constructed by a material having substituted a part of Mg in MgO with Zn.

The material constituting the tunneling layer may have a Zn content of 5 to 30 atom %.

The channel and tunneling layers may be lattice-matched to each other in at least a part of an interface therebetween.

The tunneling layer may have a thickness of 1.0 to 2.5 nm.

The ferromagnetic layer may have a single domain or a magnetization direction pinned by shape anisotropy, an antiferromagnetic film, or a synthetic film.

The spin transport device in accordance with the present invention can be employed for magnetic heads, spin transistors, memories, sensors, logic circuits, and the like.

The present invention provides a spin transport device having lowered areal resistance in its tunneling layer and a magnetic head.

### BRIEF DESCRIPTION OF THE DRAWINGS

FIG. 1 is a schematic sectional view of the magnetic sensor in accordance with an embodiment of the present invention;

FIG. 2 is a partly enlarged view of an electrode portion of the magnetic sensor illustrated in FIG. 1;

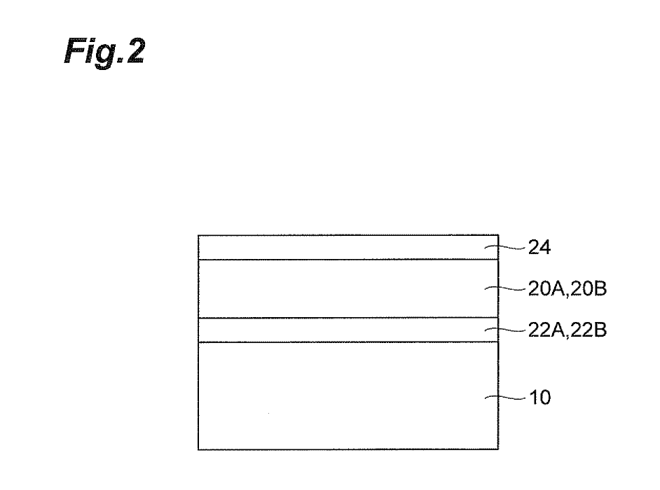

FIG. 3 is a graph illustrating the Hanle effect of the magnetic sensor illustrated in FIG. 1;

FIG. 4 is a graph illustrating the change in lattice parameter caused by the composition ratio (x) in an Mg₁₋ₓZnₓO tunnel material;

FIG. 5 is a graph illustrating the change in spin output caused by the composition ratio (x) in the Mg₁₋ₓZnₓO tunnel material;

FIG. 6 is a graph illustrating the change in areal resistance caused by the composition ratio (x) in the Mg₁₋ₓZnₓO tunnel material;

FIG. 7 is a schematic sectional view of the magnetic sensor in a mode different from that of FIG. 1;

FIG. 8 is a schematic sectional view illustrating a magnetic head including the magnetic sensor represented in FIG. 7; and

FIG. 9 is a partly enlarged view of an electrode portion in a mode different from that of FIG. 2.

### DESCRIPTION OF THE PREFERRED EMBODIMENTS

In the following, preferred embodiments of the present invention will be explained in detail with reference to the accompanying drawings. In the explanation, the same constituents or those having the same functions will be referred to with the same signs while omitting their overlapping descriptions.

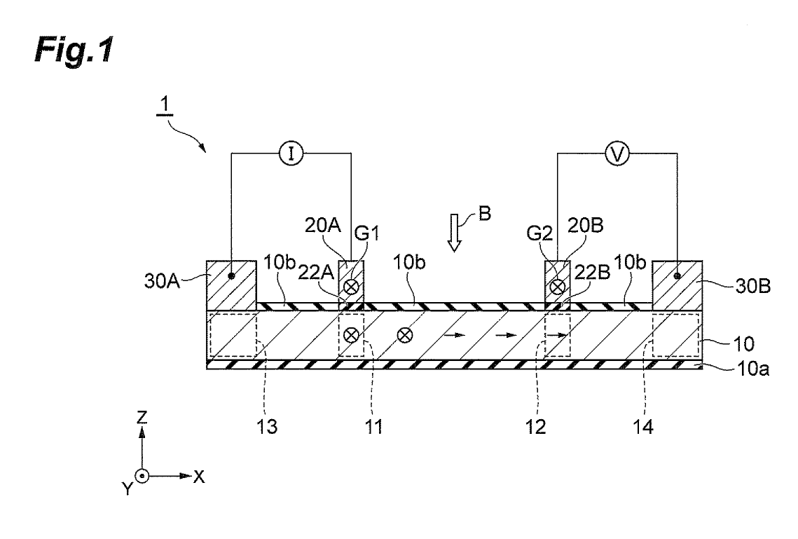

As illustrated in FIG. 1, a magnetic sensor 1, which is one of spin transport devices, has a channel layer 10, a first ferromagnetic layer 20A, and a second ferromagnetic layer 20B and detects external magnetic fields oriented along the Z axis.

The channel layer 10 extends from the first ferromagnetic layer 20A to the second ferromagnetic layer 20B and exhibits a rectangular form when seen in the thickness direction of the channel layer 10. The channel layer 10 has such a structure that electric and spin currents flow therethrough mainly along the X axis. The channel layer 10 may be doped with ions for making it conductive. The ion concentration may be 1.0×10¹⁵ to 1.0×10²²cm⁻³, for example. The channel layer 10, which is preferably a material having a long spin life, is constituted by Si. The distance between the first and second ferromagnetic layers 20A, 20B in the channel layer 10 preferably does not exceed the spin diffusion length of the channel layer 10. The channel layer 10 is not limited to Si as long as it is a semiconductor and may be constituted by GaAs, for example.

The first and second ferromagnetic layers 20A, 20B function as an injection electrode for injecting spins into the channel layer 10 or a receiving electrode for detecting spins transported through the channel layer 10. The first ferromagnetic layer 20A is disposed on a first region 11 of the channel layer 10. The second ferromagnetic layer 20B is disposed on a second region 12 of the channel layer 10.

The first and second ferromagnetic layers 20A, 20B, each having a rectangular parallelepiped form whose longer axis is oriented in the Y axis, vary in reversed field since they differ from each other in the aspect ratio between the Y and X axes. The first and second ferromagnetic layers 20A, 20B may have the same width along the Y axis but can vary in coercive force by having different widths along the X axis. As illustrated in FIG. 1, the magnetization direction G1 of the first ferromagnetic layer 20A may be identical to the magnetization direction G2 of the second ferromagnetic layer 20B. This makes it easier to pin the magnetization of the first and second ferromagnetic layers 20A, 20B.

The first and second ferromagnetic layers 20A, 20B are made of a ferromagnetic material. Preferably, the first and second ferromagnetic layers 20A, 20B are made of a metal selected from the group consisting of Cr, Mn, Co, Fe, and Ni, an alloy containing at least one element of the group, or a compound containing at least one element selected from the group and at least one element selected from the group consisting of B, C, N, Si, and Ge. These materials are ferromagnetic materials having high spin polarizability and thus can favorably achieve a function as a spin injection electrode or spin receiving electrode.

The magnetic sensor 1 further comprises a first reference electrode 30A and a second reference electrode 30B. The first reference electrode 30A is disposed on a third region 13 of the channel layer 10. The second reference electrode 30B is disposed on a fourth region 14 of the channel layer 10. The channel layer 10 extends from the first ferromagnetic layer 20A to the first reference electrode 30A in a direction different from the direction extending from the first ferromagnetic layer 20A to the second ferromagnetic layer 20B, and from the second ferromagnetic layer 20B to the second reference electrode 30B in a direction different from the direction extending from the second ferromagnetic layer 20B to the first ferromagnetic layer 20A. The first and second reference electrodes 30A, 30B are made of a conductive material, examples of which include nonmagnetic metals such as Al having a resistance lower than that of Si.

The first and second regions 11, 12 exist between the third and fourth regions 13, 14. The first reference electrode 30A, first ferromagnetic layer 20A, second ferromagnetic layer 20B, and second reference electrode 30B are arranged in this order with predetermined gaps therebetween along the X axis on the channel layer 10.

The magnetic sensor 1 further comprises tunneling layers 22A, 22B. The tunneling layers 22A, 22B are disposed between the channel layer 10 and the first and second ferromagnetic layers 20A, 20B, respectively. This makes it possible to inject spin-polarized electrons with high efficiency from the first and second ferromagnetic layers 20A, 20B into the channel layer 10, thereby enhancing the potential output of the magnetic sensor 1.

The tunneling layers 22A, 22B, which are tunnel barriers constituted by films of an insulating material, are constructed by Mg₁₋ₓZnₓO which is a material partly substituting Mg ions in MgO, which is an alkaline-earth oxide having an NaCl structure, with Zn ions. The thickness of the tunneling layers 22A, 22B is preferably 2.5 nm or less from the viewpoint of inhibiting resistance from increasing and making them function as tunnel insulating layers, but at least 1.0 nm which is a thickness by which Mg₁₋ₓZnₓO can be formed as a film.

The magnetic sensor 1 further comprises an insulating film (or insulator). The insulating film has a function for preventing the channel layer 10 from being exposed, so as to insulate the channel layer 10 electrically and magnetically. Preferably, the insulating film covers a necessary region on a surface (e.g., lower face, side face, or upper face) of the channel layer 10. Insulating films 10a, 10b are disposed on the lower and upper faces of the channel layer 10, respectively.

Specifically, the insulating film 10b is disposed on the upper faces of the regions existing between the first and second regions 11, 12 of the channel layer 10, between the first and third regions 11, 13 of the channel layer 10, and between the second and fourth regions 12, 14. This film is also disposed on the side faces of the channel layer 10. When leads connecting with the first reference electrode 30A, first ferromagnetic layer 20A, second ferromagnetic layer 20B, and second reference electrode 30B are provided on the insulating film 10b, spins of the channel layer 10 can be inhibited from being absorbed by the leads. Providing leads on the insulating film 10b can also restrain electric currents from flowing from the leads to the channel layer 10.

An example of a procedure for making the magnetic sensor 1 will now be explained.

First, an alignment mark is formed on an SOI substrate (Si 100 nm/SiOx 200 nm/Si substrate) prepared beforehand. With reference to the alignment mark, the insulating film 10a is formed on the substrate by molecular beam epitaxy (MBE), for example.

Next, the channel layer 10 is formed on the insulating film 10a by MBE, for example. Ions for making the channel layer 10 conductive are injected therein, so as to adjust a conduction characteristic thereof. Thereafter, the ions are dispersed by thermal annealing at a temperature of 900° C. Subsequently, extraneous matters, organic substances, and oxide films are removed from the surface of the channel layer 10 by RCA cleaning, and then the surface is terminated with hydrogen by using an HF cleaning solution.

Thereafter, the substrate is introduced into an MBE apparatus (with a base vacuum degree of 2.0×10⁻⁹ Torr or less), and then hydrogen is desorbed from the substrate surface upon flash annealing by heating the substrate, so as to form a clean surface. At a degree of vacuum of 5×10⁻⁸ Torr or less during deposition, films of Mg₁₋ₓZnₓO (1.2 nm) and Fe (10 nm) are formed in this order. That is, an Mg₁₋ₓZnₓO film to become the tunneling layers 22A, 22B and an Fe film (ferromagnetic film) to become the first and second ferromagnetic layers 20A, 20B are formed in this order on the channel layer 10. As a result, the channel layer 10 and the tunneling layers 22A, 22B are lattice-matched to each other in at least a part of the interface therebetween.

Next, the Mg₁₋ₓZnₓO and ferromagnetic films are processed, for example, by an electron beam (EB) method using a mask. For example, as disclosed in Japanese Patent Application Laid-Open No. 2010-199320, the channel layer 10 is formed by ion milling or chemical etching through a mask. If necessary, an antiferromagnetic layer may further be formed on the first and second ferromagnetic layers 20A, 20B by MBE, IBD, or sputtering, for example. Then, annealing under a magnetic field is performed in order to pin the magnetization direction of the first or second ferromagnetic layer 20A, 20B. Thereafter, unnecessary tunneling and ferromagnetic films formed on the channel layer 10 are removed by ion milling, for example.

Subsequently, the insulating film 10b is formed on the channel layer 10 stripped of unnecessary barrier and ferromagnetic films. The parts of the insulating film 10b on the third and fourth regions 13, 14 of the channel layer 10 are removed, so as to form the first and second reference electrodes 30A, 30B.

Operations and effects of the magnetic sensor 1 will now be explained.

To begin with, the magnetization directions of the first and second ferromagnetic layers 20A, 20B are pinned. In the example illustrated in FIG. 1, the magnetization direction G1 of the first ferromagnetic layer 20A is pinned to the same direction (along the Y axis) as with the magnetization direction G2 of the second ferromagnetic layer 20B.

For example, connecting the first ferromagnetic layer 20A and the first reference electrode 30A to an electric current source allows an electric current to flow through the first ferromagnetic layer 20A. As the electric current flows from the nonmagnetic channel layer 10 to the first ferromagnetic layer 20A, which is a ferromagnet, through the tunneling layer 22A, electrons having spins corresponding to the magnetization direction G1 of the first ferromagnetic layer 20A are injected into the channel layer 10. The injected spins diffuse toward the second ferromagnetic layer 20B. This can yield a structure in which the electric and spin currents flow through the channel layer 10 mainly along the X axis.

Here, when no external magnetic field is applied to the channel layer 10, i.e., when the external magnetic field is zero, the spins diffusing through the region between the first and second regions 11, 12 of the channel layer 10 do not rotate. Therefore, the spins having the same direction as with the preset magnetization direction G2 of the second ferromagnetic layer 20B diffuse to the second region 12. Hence, the resistance output or voltage output attains an extremum when the external magnetic field is zero. The extremum may be either a maximum or minimum depending on the direction of electric current or magnetization. The output can be evaluated by an output meter such as a voltmeter connected to the second ferromagnetic layer 20B and second reference electrode 30B.

On the other hand, a case of applying an external magnetic field to the channel layer 10 will now be considered. In the example of FIG. 1, the external magnetic field is applied along the Z axis. When the external magnetic field is applied, the spins diffusing through the channel layer 10 rotate about the axial direction of the external magnetic field (Z axis) (so-called Hanle effect). The voltage output or resistance output at the interface between the channel layer 10 and second ferromagnetic layer 20B is determined by the relative angle between the direction of rotation of the spin diffused to the second region 12 of the channel layer 10 and the preset magnetization direction G2 of the second ferromagnetic layer 20B, i.e., spin. When the external magnetic field is applied, the direction of spins diffusing through the channel layer 10 rotates, thereby deviating from the magnetization direction G2 of the second ferromagnetic layer 20B. Hence, when the external magnetic field is applied, the resistance output or voltage output becomes a maximum or lower and a minimum or higher if it takes the maximum and minimum when the external magnetic field is zero, respectively.

Therefore, the output shows a peak when the external magnetic field is zero, and decreases as the external magnetic field is enhanced or lowered. That is, the output varies depending on whether there is an external magnetic field or not, whereby the magnetic sensor 1 in accordance with this embodiment can be used as a magnetic detector.

As mentioned above, the magnetic sensor 1 yields an output peak when the external magnetic field is zero. Therefore, when reading a positive/negative timing of an external magnetic field by employing the magnetic sensor 1 for a magnetic head, for example, an output peak appears at zero where magnetic fields cancel each other out at a domain wall, whereby it can be determined that the inversion has occurred at this point. The magnetic sensor 1 is also characterized in that it has no hysteresis.

As explained in the foregoing, the tunneling layers 22A, 22B in the magnetic sensor 1 are constructed by Mg₁₋ₓZnₓO.

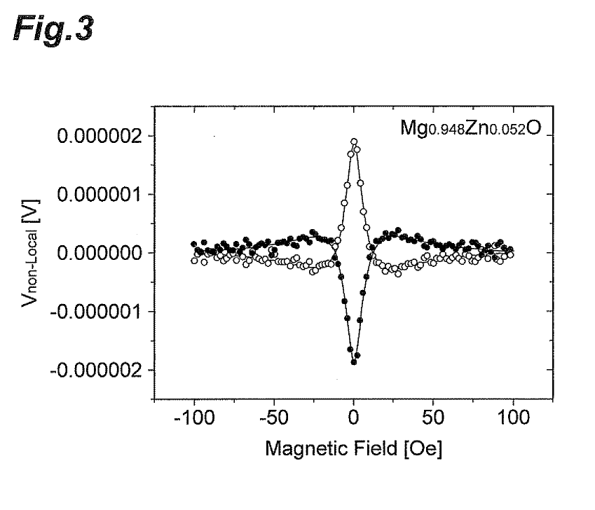

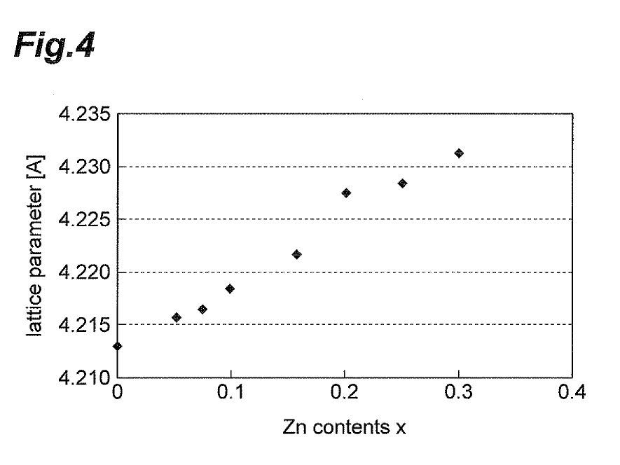

FIG. 3 is a graph evaluating the Hanle effect of a spin current at 8 K when using Mg_{0.948}Zn_{0.052}O as a tunnel material, while FIGS. 4 to 6 are graphs representing the values of lattice parameter, spin output, and areal resistance obtained when changing the composition ratio (x) in an Mg₁₋ₓZnₓO tunnel material, respectively.

It is seen from the graph of FIG. 4 that the lattice parameter increases in proportion to the Zn content. This indicates that Mg ions in MgO are partly substituted with Zn.

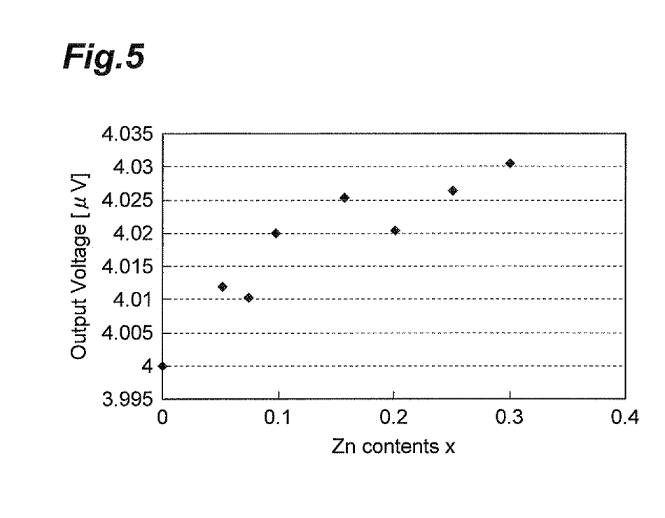

The graph of FIG. 5 determines the spin output from the Hanle effect and represents its relationship with added Zn, from which the output is seen to increase slightly as the Zn content becomes greater.

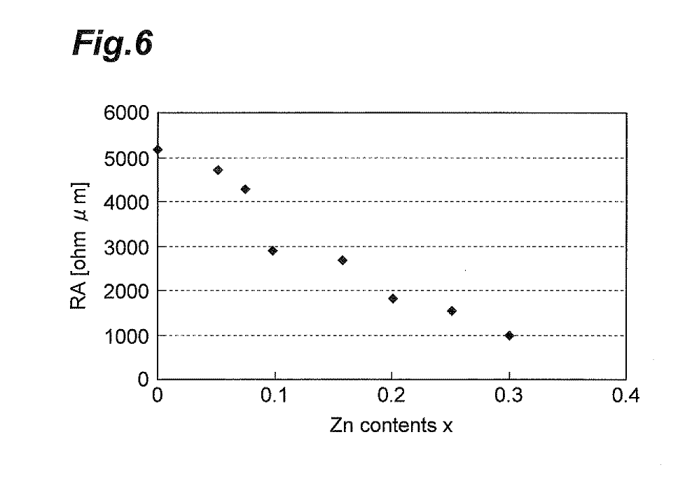

It is seen from the graph of FIG. 6 that the areal resistance (RA) decreases as Zn increases. The areal resistance at the Zn content of 30 atom %, which is the maximum amount of Zn used for substitution, decreases to about ⅕ that of the totally unsubstituted material (i.e., MgO material).

Since the areal resistance thus decreases in a tunnel material partly substituting Mg in MgO with Zn, the tunneling layers 22A, 22B can lower their areal resistance when constructed by a material in which Mg in MgO is partly substituted with Zn.

Here, X-ray diffraction shows no impurities up to 30 atom % substitution by Zn, while exhibiting a systematic change in lattice parameter, which seems to indicate that Mg is certainly substituted with Zn. Also, as illustrated in the graph of FIG. 5, the spin output slightly increases as the amount of substitution by Zn becomes greater. This seems to be an improvement under the influence of the difference in lattice parameter between the silicon and tunneling layers caused when MgO enhances its lattice parameter upon substitution by Zn.

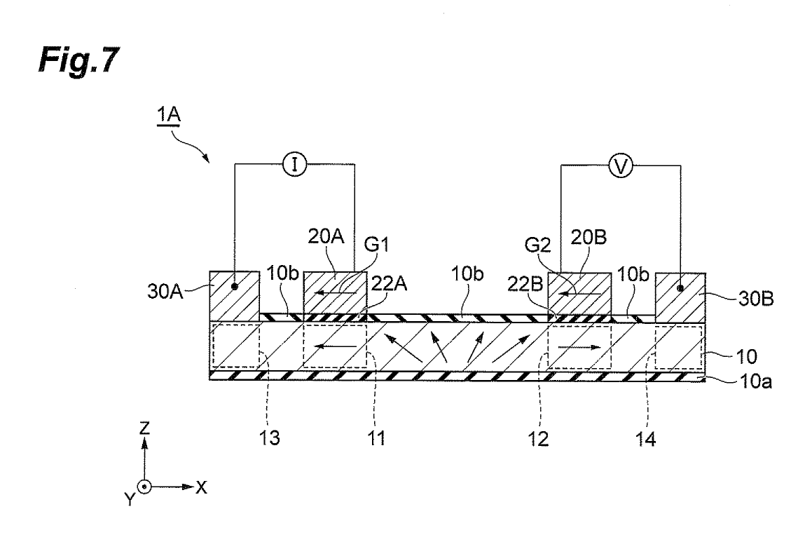

The magnetic sensor 1 in accordance with one embodiment of the present invention can be employed for magnetic heads, spin transistors, memories, sensors, logic circuits, and the like. When optimizing the magnetic sensor for a magnetic head, the external magnetic field is preferably made incident thereon along the Y axis illustrated in FIG. 1. In this case, as in the magnetic sensor 1A illustrated in FIG. 7, the magnetization direction of the ferromagnetic layers 20A, 20B is pinned to the X axis (or Z axis). Preferably, the magnetization direction of the ferromagnetic layers 20A, 20B is pinned to the X axis by using an antiferromagnetic film or a perpendicularly magnetized film having magnetic anisotropy along the Z axis.

The above-mentioned perpendicularly magnetized film is made of TbFeCo, FePt, CoPt, FePd, MnAl, or CrCo, for example. Other examples of its material include a metal selected from the group consisting of Al, Cr, Mn, Co, Fe, Ni, Pd, Pt, and Tb, an alloy containing at least one element of the group, or a compound containing at least one element selected from the group and at least one element selected from the group consisting of B, C, N, Si, and Ge.

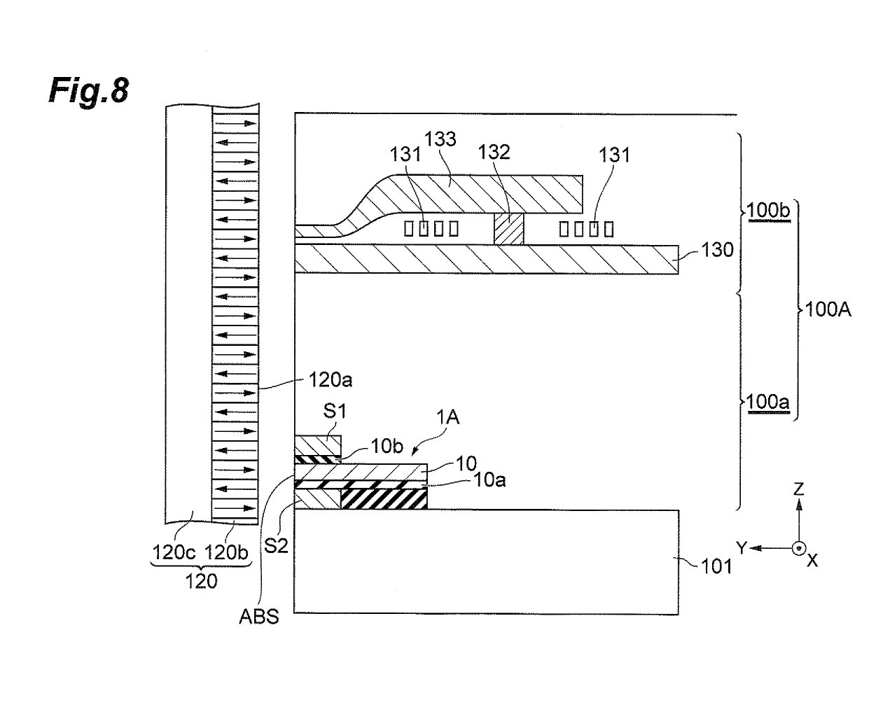

FIG. 8 is a schematic sectional view illustrating a magnetic head 100A which is a thin-film magnetic recording and reproducing head. The above-mentioned magnetic sensor 1A of FIG. 7 can be employed for a read head unit 100a of the magnetic head 100A. The magnetic head 100A acts to record and read magnetic information at such a position that its air bearing surface (medium-opposing surface) ABS opposes a recording surface 120a of a magnetic recording medium 120. The front end face of the channel layer 10 of the magnetic sensor 1A (on the front side of the drawing sheet of FIG. 7) is arranged such as to correspond to the air bearing surface ABS.

The magnetic recording medium 120 includes a recording layer 120b having the recording surface 120a and a soft-magnetic backing layer 120e laid on the recording layer 120b and advances relative to the magnetic head 100A along the Z axis in FIG. 8. The magnetic head 100A further comprises a write head unit 100b for recording onto the magnetic recording medium 120 in addition to the read head unit 100a for reading records from the magnetic recording medium 120. The read head unit 100a and write head unit 100b are disposed on a substrate 101 and covered with a nonmagnetic insulating layer such as alumina.

As illustrated in FIG. 8, the write head unit 100b is disposed on the read head unit 100a. In the write head unit 100b, a contact part 132 and a main magnetic pole 133 are disposed on a return yoke 130, so as to form a magnetic flux path. A thin-film coil 131 is provided so as to surround the contact part 132. When a recording current is caused to flow through the thin-film coil 131, the leading end of the main magnetic pole 133 releases a magnetic flux, whereby information can be recorded on the recording layer 120b of the magnetic recording medium 120 such as a hard disk. As in the foregoing, the magnetic head 100A that can detect magnetic fluxes from minute areas of recording media and the like can be provided by using the magnetic sensor 1.

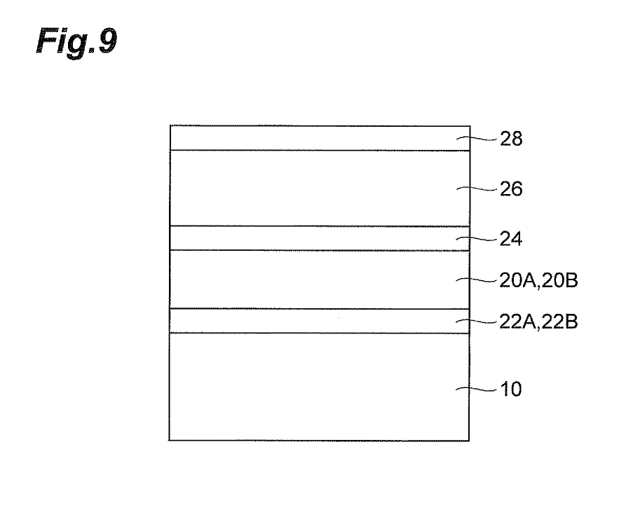

The present invention can be modified in various ways without being limited to the above-mentioned embodiment. For example, the electrode structure about the first and second ferromagnetic layers 20A, 20B may be a multilayer structure magnetized by synthetic films as illustrated in FIG. 9. The multilayer structure of FIG. 9 is one in which Mg₁₋ₓZnₓO (thickness: 1.2 nm), Fe (thickness: 10 nm), Ru (thickness: 1.5 nm), and Ta (thickness: 1.5 nm) are formed sequentially and corresponds to the channel layer 10, the tunneling layers 22A, 22B, the ferromagnetic layers 20A, 20B, a protective layer 24, an Ru layer 26, and a ferromagnetic layer 28.

The magnetization direction of the first and second ferromagnetic layers 20A, 20B may be pinned by an antiferromagnetic layer disposed thereon or shape anisotropy. For example, the first and second ferromagnetic layers 20A, 20B may be varied in reversed field by a difference in the aspect ratio between the X and Y axes. Alternatively, the first and second ferromagnetic layers 20A, 20B may be provided with an antiferromagnetic layer for pinning their magnetization direction. This allows the first or second ferromagnetic layer 20A, 20B to have higher coercive force in one direction than without the antiferromagnetic layer.

What is claimed is:

1. A spin transport device comprising:
a channel layer constituted by a semiconductor;
a ferromagnetic layer formed on the channel layer; and
a tunneling layer formed so as to be interposed between the channel and ferromagnetic layers;
wherein the tunneling layer is constituted by a material substituting a part of Mg in MgO with Zn.

2. The spin transport device according to claim 1, wherein the material constituting the tunneling layer has a Zn content of 5 to 30 atom %.

3. The spin transport device according to claim 1, wherein the channel and tunneling layers are lattice-matched to each other in at least a part of an interface therebetween.

4. The spin transport device according to claim 1, wherein the tunneling layer has a thickness of 1.0 to 2.5 nm.

5. The spin transport device according to claim 1, wherein the ferromagnetic layer has a single domain.

6. The spin transport device according to claim 5, wherein the ferromagnetic layer has a magnetization direction pinned by shape anisotropy.

7. The spin transport device according to claim 5, wherein the ferromagnetic layer has a magnetization direction pinned by an antiferromagnetic film.

8. The spin transport device according to claim 5, wherein the ferromagnetic layer has a magnetization direction pinned by a synthetic film.

9. A magnetic head comprising the spin transport device according to claim 1.
